(19) United States
(12) Patent Application Publication
(10) Pub. No.: US 2008/0121369 A1
(43) Pub. Date: May 29, 2008

(54) HEAT DISSIPATION ASSEMBLY HAVING FAN DUCT

(75) Inventors: JUN LONG, Shenzhen (CN); YONG ZHONG, Shenzhen (CN); HAO LI, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignee: FOXCONN TECHNOLOGY CO., LTD., Tu-Cheng (TW)

(21) Appl. No.: 11/564,273

(22) Filed: Nov. 28, 2006

(51) Int. Cl. H05K 7/20

(52) U.S. Cl. 165/80.3; 361/697; 165/121

(57) ABSTRACT

A heat dissipation assembly (100) comprises a heat sink (10) having a plurality of fins (120), a fan (20) mounted onto the heat sink (10) for generating an airflow flowing into a plurality of channels (126) between the fins (120) of the heat sink (10) and a ventilating strip (40) encircling an outer periphery of the fins (120) to prevent the airflow generated by the fan (20) from being prematurely dispersed out of the fins (120) via the channels (126). The ventilating strip (40) helps the airflow to more effectively reach a bottom of the heat sink (10), which is used to contact a heat-generating electronic component.

### BACKGROUND OF THE INVENTION

1. Field of the Invention

The present invention relates generally to a heat dissipation assembly, and particularly to a heat dissipation assembly having a ventilating strip for preventing airflow generated by a fan from being dispersed therefrom.

2. Description of Related Art

Electronic devices such as central processing units (CPUs) generate a lot of heat during normal operation. If the heat generated by the electronic devices is not properly dissipated, it can deteriorate their operational stability and damage associated electronic devices. Thus the heat must be quickly and efficiently removed to ensure the normal operation of these electronic devices. Oftentimes, a heat dissipation assembly is used to dissipate heat from electronic devices. The heat dissipation assembly frequently comprises a heat sink and a fan. The heat sink can be mounted in contact with the CPU inside a computer. The fan is usually positioned on the heat sink and generates a high-pressured airflow blowing downwards into the heat sink, causing the heat to be dissipated into the surroundings.

A related heat dissipation assembly 90 is disclosed in FIG. 3. The heat dissipation assembly 90 generally comprises a heat sink 92, a fan 96 and a fan bracket 94. The heat sink 92 comprises a cylinder-shaped central core (not shown) and a plurality of fins 922 radially extending outwardly from the central core. The fan 96 is mounted above the heat sink 92 via the fan bracket 94 buckled to a top portion of the heat sink 92. The fan 96 draws outside cooling air downwardly onto the heat sink 92 secured on a CPU (not shown). Due to the fins 922 being configured extending radially, airflow generated by the fan 96 is dispersed out of the fins 922 along various directions of the fins 922 before reaching a bottom portion of the heat sink 92 where large amounts of heat accumulate. Thus, the related heat dissipation device 90 has lessened heat-dissipating efficiency. In other situations, a fan duct can be formed at a bottom edge of the fan bracket 94, thus more airflow from the fan 96 can be conducted to the bottom portion of the heat sink 92. However, it is expensive to mount the fan duct to the heat sink and cannot be easily adapted to fit different sized heat sinks.

### SUMMARY OF THE INVENTION

According to a preferred embodiment of the present invention, a heat dissipation assembly comprises a heat sink having a plurality of fins, a fan mounted onto the heat sink for generating an airflow flowing into a plurality of channels between the fins of the heat sink, and a ventilating strip encircling an outer periphery of the fins to prevent the airflow generated by the fan from being prematurely dispersed out of the fins via the channels.

Other advantages and novel features of the present invention will become more apparent from the following detailed description of the preferred embodiment when taken in conjunction with the accompanying drawings, in which:

### BRIEF DESCRIPTION OF THE DRAWINGS

Many aspects of the present device can be better understood with reference to the following drawings. The components in the drawings are not necessarily drawn to scale, the emphasis instead being placed upon clearly illustrating the principles of the present device. Moreover, in the drawings, like reference numerals designate corresponding parts throughout the several views.

FIG. 1 is an assembled, isometric view of a heat dissipation assembly in accordance with a preferred embodiment of the present invention;

FIG. 2 is an exploded view of FIG. 1; and

FIG. 3 is an assembled, isometric view of a heat dissipation assembly in accordance with the related art.

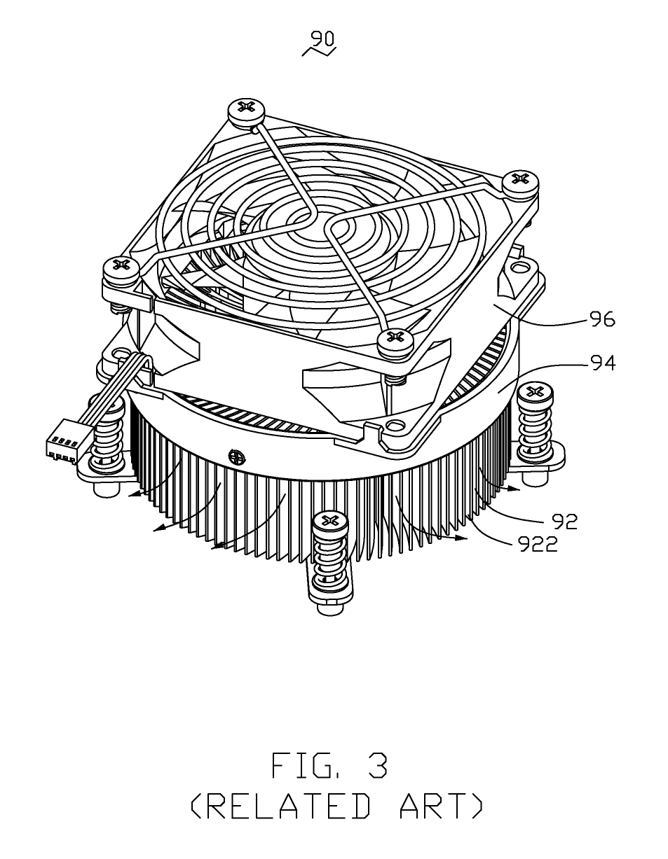

### DETAILED DESCRIPTION OF THE INVENTION

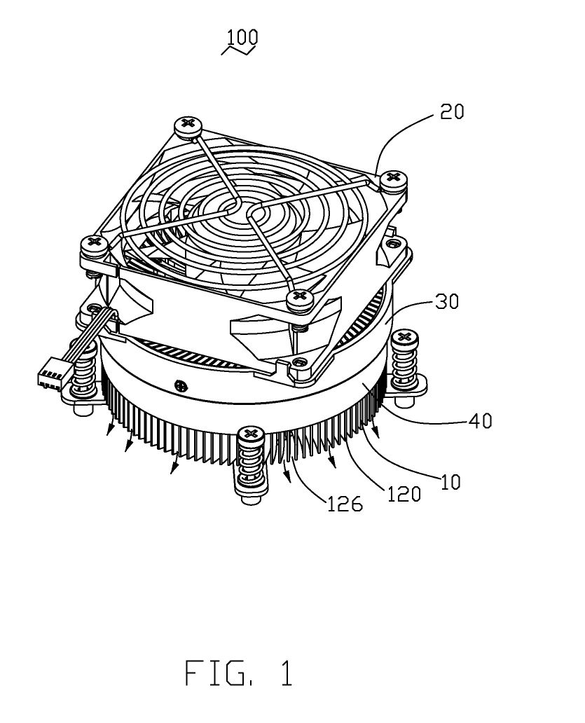

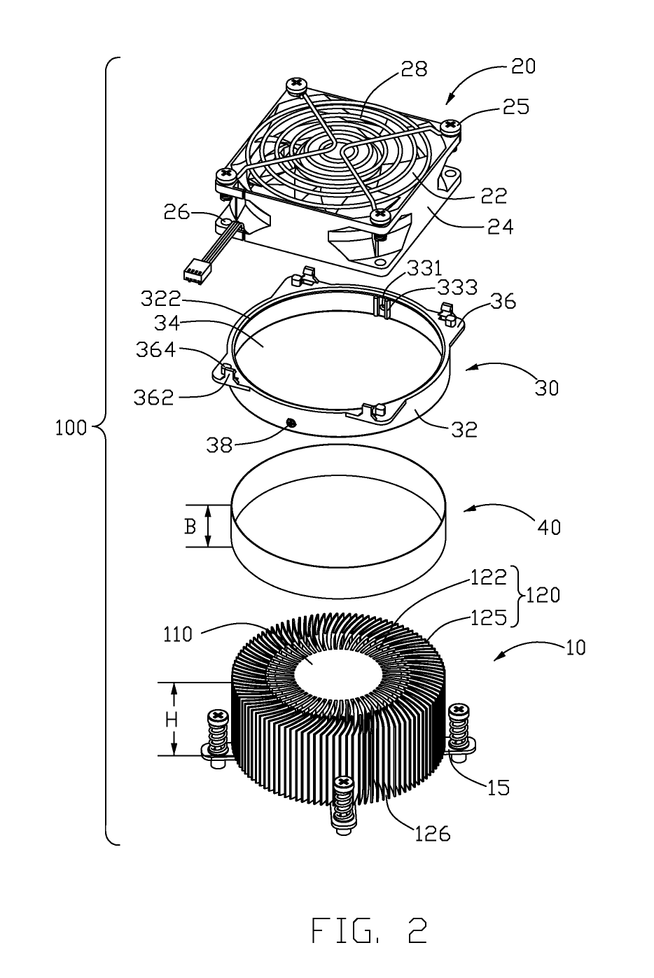

Referring to FIG. 1 and FIG. 2, a heat dissipation assembly 100 comprises a heat sink 10, a fan bracket 30, a fan 20 mounted on the heat sink 10 via the fan bracket 30 for providing a forced airflow to the heat sink 10 and a ventilating strip 40. The ventilating strip 40 abutting against the fan bracket 30 encircles an outer circumferential periphery of the heat sink 10, and is employed as a fan duct to conduct the airflow generated by the fan 20 to flow to the heat sink 10 for preventing the airflow from being prematurely dispersed out of the heat sink 10.

The heat sink 10 has a cylindrical configuration and comprises a central core 110 with a cylinder-like shape and a plurality of radial fins 120 radially extending outwardly from the core 12. The fins 120 are all curved in a similar direction, such as the clockwise direction, and are of same extension length. The fins 120 have a height H, which is the same as that of the core 120. Each fin 120 has a main portion 122 integrally connecting with the core 12 and two offsetting portions 125 integrally branching outwardly from a free end of the main portion 122. The fins 120 are spaced from each other at uniform intervals, thus a plurality of channels 126 for the airflow to flow therein is defined between the fins 120. A locking device 15 is attached to a bottom portion of the heat sink 10 and adapted to secure the heat sink 10 onto a printed circuit board (not shown) having a heat-generating electronic device (not shown) thereon.

The fan 20 has a frame 24 and a plurality of rotor blades 22 radially arranged in the frame 24. The frame 24 has a square configuration and comprises four corners. A locating hole 26 is defined in each corner of top and bottom portions of the frame 24. A fan guard 28 can be arranged on the top portion of the frame 24 to prevent hands from touching the rotor blades 22 when the fan 20 is operated. The fan guard 28 can have a square and grill-like construction corresponding to the frame 24 of the fan 20 and can be made of metal wire. Four through holes (not labeled), corresponding to the locating holes 26 of the fan 20, are defined at four corners of the fan guard 28. Four screws 25 are inserted through the through holes of the fan guard 28 and engaged in the locating holes 26 of the top portion of the frame 24 of the fan 20, thus attaching the fan guard 28 to the fan 20.

The fan bracket 30 comprises an annular frame 32 and a central opening 34 defined therein. A collar flange 322 extends inwardly and horizontally from a top edge of the frame 32. Four symmetrical ears 36 outwardly and horizontally extend from an outer edge of a top portion of the frame 32. Four catches 362 perpendicularly extend upwardly from top surfaces of the ears 36 for engaging with lower corners of the fan 20. A pin 364 spaced from each catch 362 is formed upwardly on each ear 36 for engaging in each corresponding locating hole 26 of the fan 20. Thus the fan 20 can be fittingly mounted on the fan bracket 30 via the ears 36 and exposed to the heat sink 10 through the opening 34 of the fan bracket 30. Two opposite holes 331 are defined through the frame 32 in a horizontal direction, each located in a middle of two neighboring ears 36. Two pairs of elongated ribs 333 extend vertically, each protruding out in parallel beside each through hole 331 from an inner surface of the frame 32. Each through hole 331 is located between the pair of ribs 333. A top portion of the heat sink 10 is received in the opening 34 of the fan bracket 30 with the collar flange 322 of the bracket 30 abutting an edge of the top portion of the heat sink 10. Thus the frame 32 embraces the outer circumferential periphery of the top portion of the heat sink 10. Two self-tapping screws 38 are inserted into the through holes 331 and further threadedly engage in the channel 126 between two adjacent offsetting portions 125 of the fin 120 sandwiched between the pair of ribs 333 by self-tapping. Thus the fan bracket 30 is attached to the heat sink 10 securely.

The ventilating strip 40 is formed as a circular loop by connecting two ends of a strap. The ventilating strip 40 can be made of a substance chosen from the group consisting of, but is not limited to, adhesive tape, fabric, elastoplastic, metal and any suitable combination of these substances. The ventilating strip 40 is arranged intimately extending away from a bottom edge of the fan bracket 30 and encircling the outer circumferential periphery of the heat sink 10, thus forming a fan duct around the heat sink 10. The ventilating strip 40 has a height B that is determined according to the height H of the heat sink 10 in order to conduct the airflow generated by the fan 20 to the heat-generating electronic device located below the heat sink 10 more efficiently.

In use, the heat generated by the heat-generating electronic device is absorbed by the core 12 and the fins 120 of the heat sink 10, and subsequently transferred to the top portion of the heat sink 10. The fan 20 generates an airflow and blows the airflow into the channels 126 of the heat sink 10 through the opening 34 of the fan bracket 30. Because the channels 126 are enclosed by the fins 120, the fan bracket 30 and the ventilating strip 40. The airflow is thus forced to flow downwardly along side surfaces of the fins 120. Furthermore, a large amount of the airflow having high pressure can reach the bottom portion of the heat sink 10 where a large amount of heat accumulates. It is obvious that heat-dissipation efficiency of the heat dissipation assembly having the ventilating strip 40 is enhanced compared with the one without the ventilating strip 40. In addition, the ventilating strip 40 can be applied in other heat sinks 10 having different shapes or sizes by simply changing the size of the ventilating strip 40. Thus, the ventilating strip 40 can be fittingly used in a variety of heat dissipation assemblies.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation assembly, comprising:
a heat sink having a plurality of fins thereon, with a plurality of channels being defined between the fins;
a fan mounted onto the heat sink for generating an airflow flowing into the channels; and
a ventilating strip encircling an outer periphery of the fins at a location near the fan to prevent the airflow generated by the fan from being prematurely dispersed out of the fins via the channels.

2. The heat dissipation assembly as claimed in claim 1, wherein the heat dissipation assembly comprises a fan bracket buckled with a top portion of the heat sink, the fan is mounted on the fan bracket.

3. The heat dissipation assembly as claimed in claim 2, wherein the ventilating strip is arranged intimately abutting against a bottom edge of the fan bracket.

4. The heat dissipation assembly as claimed in claim 2, wherein the ventilating strip is made of a substance chosen from the group consisting of adhesive tape, fabric, elastoplastic, metal, and any suitable combination of these substances.

5. The heat dissipation assembly as claimed in claim 2, wherein the heat sink comprises a central core, the fins radially extend outwards from the core.

6. The heat dissipation assembly as claimed in claim 5, wherein the core of the heat sink has a cylinder-like shape.

7. The heat dissipation assembly as claimed in claim 6, wherein the fins are all curved in a same direction with a same extending length, the heat sink has a cylindrical configuration.

8. The heat dissipation assembly as claimed in claim 7, wherein each of the fins has a main portion integrally connecting with the core and two offset portions integrally branching outwardly from a free end of the main portion.

9. The heat dissipation assembly as claimed in claim 2, wherein the fan bracket comprises an annular frame, and wherein an opening is defined therein and a flange extends inwardly and horizontally from a top portion of the frame of the fan bracket for abutting a top edge of the heat sink.

10. The heat dissipation assembly as claimed in claim 9, wherein the frame defines two opposite horizontal holes therethrough and comprises a pair of elongated vertical ribs beside each horizontal hole, the pair of elongated ribs receiving a corresponding fin therein, screws being extended through the horizontal holes to engage with the corresponding fins in the vertical ribs.

11. A heat dissipation assembly, comprising:
a heat sink having a plurality of fins thereon, with a plurality of channels being defined between the fins;
a fan bracket connected with the heat sink, a central opening defined in the fan bracket;
a fan connected with the fan bracket and exposed to the heat sink through the opening of the fan bracket;
a ventilating strip extending away from the fan bracket and encircling an outer periphery of the heat sink to prevent airflow generated by the fan from being prematurely dispersed out of the heat sink via the channels.

12. The heat dissipation assembly as claimed in claim 11, wherein the ventilating strip is made of adhesive tape.

13. The heat dissipation assembly as claimed in claim 11, wherein the heat sink comprises a central core, the fins radially extend outwards from the core.

14. The heat dissipation assembly as claimed in claim 13, wherein the core of the heat sink has a cylinder-like shape, the fins are all curved in a same direction with a same extending length, the heat sink has a cylindrical configuration.

15. The heat dissipation assembly as claimed in claim 14, wherein each of the fins has a main portion integrally connecting with the core and two offsetting portions integrally branching outwardly from a free end of the main portion.

16. The heat dissipation assembly as claimed in claim 11, wherein the fan bracket comprises an annular frame, and wherein a flange extends inwardly and horizontally from a top portion of the frame for abutting a top edge of the heat sink.

17. The heat dissipation assembly as claimed in claim 16, wherein the frame defines two opposite horizontal holes therethrough and comprises a pair of elongated vertical ribs beside each horizontal hole, the pair of elongated vertical ribs receiving a corresponding fin therein, screws being extended through the horizontal holes to engage with the corresponding fins in the vertical ribs.
